(19) United States
(12) Patent Application Publication
(10) Pub. No.: US 2004/0118445 A1
(43) Pub. Date: Jun. 24, 2004

(54) Thin-film solar modules with reduced corrosion

(76) Inventor: Nick Dalacu, Niagara Falls, NY (US)

Correspondence Address: Nick DALACU, 1658 Ontario Ave, Niagara Falls, NY, 14305-0191, US

(21) Appl. No.: 10/326,941

(22) Filed: Dec. 23, 2002

(51) Int. Cl. H01L 31/00

(52) U.S. Cl. 136/244; 136/256

(57) ABSTRACT

A thin-film solar module with an array of photovoltaic cells is provided on a soda-lime transparent substrate of a first area. The substrate supports the array on a second area; the first area extends beyond the second area by a stripped peripheral zone. This arrangement results in reduced corrosion of the substrate and the cathode. In addition, the life of the module is further extended if the module is protected against atmospheric humidity with a cover that leaves an air cavity about the array. In a variant of this arrangement, an isolated strip of the same material as the cathode is provided within the stripped peripheral zone, around the perimeter of the second area.

### FIELD OF THE INVENTION

This invention is directed to reducing corrosion in thin-film solar cells and modules made on soda-lime glass. In this document, “solar module” refers solely to photovoltaic devices.

### BACKGROUND OF THE INVENTION

Use of environmentally friendly energy has received increased attention in the last decade. Photovoltaic devices such as solar cells and photodetectors are capable of converting solar radiation into usable electrical energy. Currently, there is extensive research in making solar energy more competitive in terms of efficiency, stability and cost.

Thin-film solar cells offer good chances of significantly reducing the costs for producing highly efficient solar modules. A solar module is made of solar cells that are electrically connected to provide electrical power. The assembly of solar cells (i.e., the module) is usually supported on a rigid base. Each individual cell has an anode and a cathode separated by a semiconductor photoactive layer. The anode and cathode of each cell are interconnected with those of the neighboring cells, in series or in parallel, so that module generates a certain voltage and current for a particular load (e.g., a battery). Compound semiconductors such as cadmium sulfide (CdS), cadmium telluride (CdTe), copper-indium selenide (CIS), copper sulfide, gallium arsenide (GaAs), indium phosphide (InP) and zinc telluride (ZnTe) have been used extensively for photoelectric device materials in the solar industry.

Large thin-film modules may contain hundreds of cells. As a cell produces approximately 0.8 V under a reasonably high illumination level, thin-film solar modules are able to produce high voltages.

Usually, modules are built on a glass substrate, which allows light to reach the cell, and which also serves as environmental protection and as a rigid support for the cells. The cell layers and the interconnections between cells are deposited on the substrate. The first and last cells in the module are connected to the external leads or terminals.

Because of the experience with crystalline-silicon modules, glass substrates were considered inert, and therefore it was assumed that the glass could not contribute to module deterioration. However, it has been observed that glass can be affected by moisture. More specifically, after a certain time in the field, the alkali from the glass will leach out, leaving hydrated pores, which results in glass corrosion.

Furthermore, when the module is exposed to adequate light intensities, the SnO₂ film is at a potential of approximately −0.8 V with respect to the back contact of the cell. Condensation at the edge of the glass, contained within the field produced by the back-contact anode and the adjacent SnO₂ cathode, will trigger migration of Na+that will accumulate under the SnO₂ layer. The Na+will reduce the Sn from SnO₂. The byproduct of the reaction will be porous and water absorbing, which will further increase the rate of corrosion. Ultimately, this phenomenon results in delamination of the SnO₂ layer.

There is a need to reduce corrosion in thin-film solar modules, caused by ambient humidity and temperature.

### SUMMARY OF THE INVENTION

It is an object of the invention to reduce degradation of thin-film solar modules, made on soda-lime glass.

Accordingly, the invention provides a thin-film solar module having a plurality of photovoltaic cells for converting light into electrical voltage, the cells being connected to each other to obtain a target voltage, a cell having the cathode layer deposited on the cell area, a photoactive layer deposited on the cathode layer and an anode layer deposited on the photoactive layer, the module comprising: a transparent substrate of a first area for supporting the cells on a second area, while allowing light to reach the cells environmentally protecting the cells; and a positive bus bar connected to the anode of a first cell of the module and a negative bus bar connected to the cathode of a last cell of the module, wherein the first area extends beyond the second area by a stripped peripheral zone.

According to another aspect, the invention provides a thin film solar module comprising: a soda-lime glass substrate having a first area; and a plurality of photovoltaic cells supported on the glass substrate, the cells arranged in an array occupying a second area on the first area, wherein the second area is arranged to leave a peripheral zone of the glass around the array.

Advantageously, the solution proposed for the solar modules and arrays (interconnected modules) according to the invention is simple and results in a low-cost enhancement to the modules. In particular, by addressing corrosion, the present invention results in solar modules that have reduced degradation and correspondingly increased operating lifetime.

### BRIEF DESCRIPTION OF THE DRAWINGS

Further advantages, features and details of the invention will be apparent from the following description of the preferred embodiments with reference to the drawings, in which:

FIG. 1 illustrates a cross-section of a CdTe based solar module, showing how the cells of a module are connected to each other in series;

FIG. 2A illustrates a top view of an embodiment of a six-cell module with a corrosion protection perimeter (all film coatings removed, i.e., bare glass) according to the invention;

FIG. 2B shows a cross-section of the embodiment of FIG. 2A illustrating the protection cover;

FIG. 3A illustrates a top view of another embodiment of a six-cell module with a cathodic—protection perimeter according to the invention;

FIG. 3B shows a cross-section of the embodiment of FIG. 3A illustrating the protection cover.

### DETAILED DESCRIPTION

FIG. 1 illustrates a cross-section of a typical CdTe based solar module 1. It is to be noted that the illustration in FIG. 1 is not to scale. The substrate 2 is soda-lime glass, with a thickness of approximately 3-5 mm. A typical recipe for soda-lime glass may contain approximately 15% of sodium oxide (Na₂O). FIG. 1 shows two adjacent cells 3-1 and 3-2, separated from each other, such as shown for example by a grove 11. Each cell has a layered cross-section.

A tin oxide (SnO₂) cathode 4-1, 4-2 is deposited on the substrate 2 as a 1-μm thick film. The next layer on top of the cathode is preferably a cadmium sulfide (CdS) semiconductor film 6-1, 6-2, which has in general a thickness of 0.1 μm. The next layer, a high resistivity absorber layer 8-1, 8-2, is preferably a 4-μm thick CdTe film deposited over the CdS layer. The anode 10-1, 10-2 is then deposited on the back of the cell. It is to be noted that terms “front” and “back” are relative terms with respect to the side on which the light impinges on the module. In this specification, the term “back” refers to the side of the module with the anode, which does not receive the light. The “front” is the side with the transparent glass support and transparent cathode that allow light to illuminate the photoactive semiconductor layer.

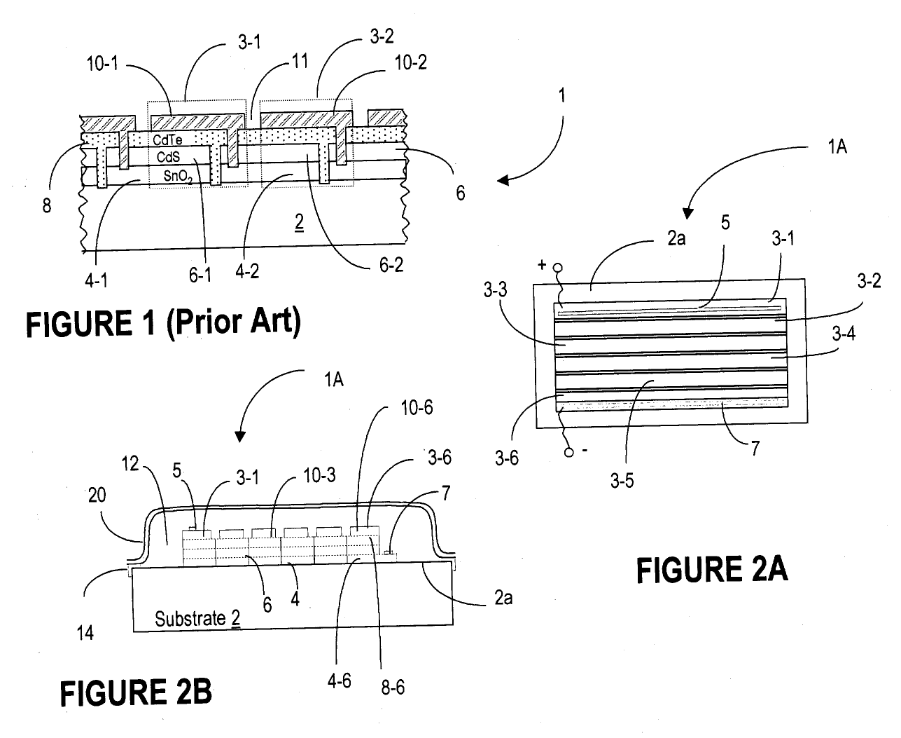

A cell, such as the cells shown at 3-1 and 3-2, generates approximately 0.8 V between the anode and the cathode, under normal illumination conditions. FIG. 1 also shows how the anode 10-1 of cell 3-1 is series-connected to the cathode 4-2 of the adjacent cell 3-2. The voltage from all cells is collected by a positive bus bar 5 and respectively a negative bus bar 7 (see FIG. 2A) provided along the first and last cells of a module. The bus bars are connected to leads and/or terminals that allow connection to other modules and/or loads.

The CdTe film 8-1 has high resistivity and, as such, prevents current flow between the CdS films 6-1 and 6-2 of adjacent cells. On the other hand, the current can flow easily between the anode 10-1 and cathode 4-2 of adjacent cells 3-1 and 3-2.

As indicated above, it has been observed that the glass substrate 2 and the SnO₂ film 4 are in fact affected by moisture. More specifically, the alkali from the glass leaches out and migrates in time towards the SnO₂ layer, leaving hydrated pores in the substrate. In the presence of an electric field (when the module is illuminated), the alkali ions migrate and reduce Sn from the SnO₂ cathode, resulting in further module degradation caused by corrosion. The module degradation increases with the field. Moisture at the edges of the modules is particularly damaging.

In order to reduce corrosion of the substrate 2 and of the SnO₂ film, the present invention proposes to improve isolation of the module from the ambient humidity by stripping the SnO₂ film at the periphery of the module. In other words, the glass substrate has a certain area (first area), while the array of cells (or the module) occupies a second, smaller area, leaving a peripheral zone of glass around the module. This zone may be as large as practical. FIG. 2A shows a simplified top view of the module 1, where the cells are shown by reference numeral 3 followed by the number of the cell in the module, and the stripped glass zone is shown at 2a. Similarly, the reference number for the layers of each cell is followed by the number of the cell in the module.

The module 1 and the stripped area are encapsulated using a suitable cover, which leaves an air cavity at the back of the module. FIG. 2B shows the module encapsulated using cover 20, and the air cavity at 12. The cover 20 is attached to the glass substrate as shown at 14. Preferably, the cover is attached using, for example, a butyl adhesive.

Use of the cover 20 reduces substantially ingress of atmospheric moisture into the module. It also reduces significantly the dissolution of the Na⁺ ions and/or electro-migration of these ions towards the SnO₂ layer, with the corresponding reduction of the Sn and the delaminating effects of the products of this reaction. FIGS. 2A and 2B also show how the bus bars 5 and 7 connect the anode of the first cell 3-1 and the cathode of the last cell 3-6 with the external positive and respectively negative contacts, where the respective voltage is obtained. Bus bar 5 is connected at the back of cell 3-1, where it contacts the anode 10-1. Bus bar 7 is connected to the cathode 4-6 of the last cell 3-6; this cathode extends beyond layers 6-6, 8-6 and 10-6, as shown. It is to be noted that this is an example and other ways to connect the bus bars may be envisaged.

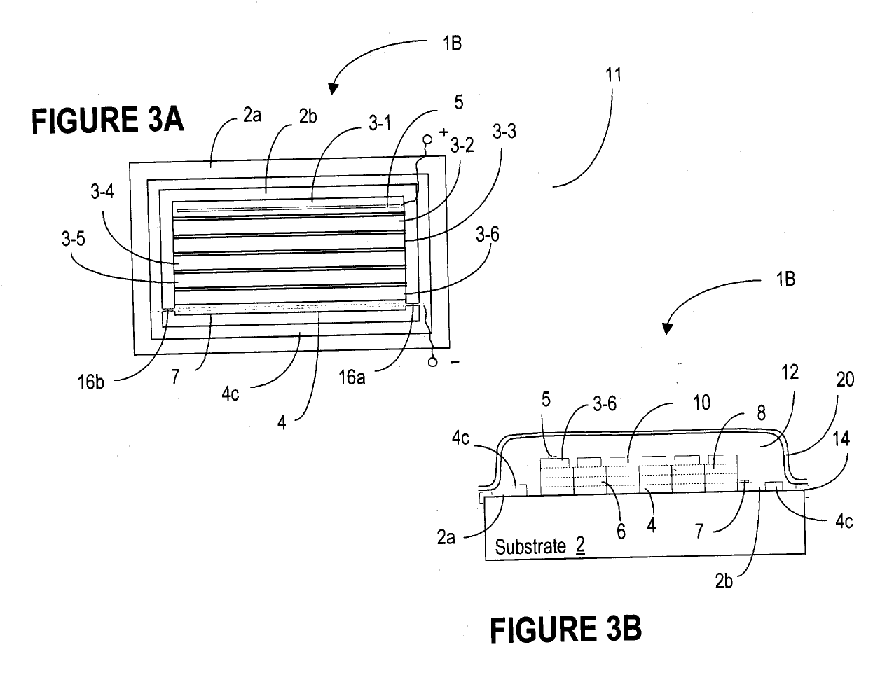

Another embodiment of the module according to the invention is illustrated in FIG. 3A. In this embodiment, the module is surrounded by an isolated strip 4c of SnO₂ provided around the perimeter of the module. The strip 4c is bordered on both sides by stripped glass, as shown at 2a and 2b. Strip 4c is connected to the lowest voltage electrode, namely the cathode of the first cell in the module, as shown at 16a and 16b in FIG. 3A. As a result, the Na⁺ ions are repulsed, even in the presence of water molecules, and the corrosion of SnO₂ is substantially reduced.

FIG. 3B shows the encapsulated version of the module 1B, where cover 20 is fixed on the substrate at 14 and leaves an air cavity 12 at the back of the module.

The air cavity 12 provided at the back of the module is preferably used to actively circulate dry air along the back of the cells when the module is exposed to solar radiation. This circulating air can be flowed through a heat exchanger in order to extract the thermal energy collected from the module(s), as described in the U.S. Pat. No. 6,201,179 (Dalacu) issued on Mar. 13, 2001. Up to approximately 40% of the incident solar radiation can be extracted by this method.

I claim:

1. A thin-film solar module having a plurality of photovoltaic cells for converting light into electrical voltage, said cells being connected to each other to obtain a target voltage, a cell having said cathode layer deposited on said cell area, a photoactive layer deposited on said cathode layer and an anode layer deposited on said photoactive layer, said module comprising:
a transparent substrate of a first area for supporting said cells on a second area, while allowing light to reach said cells environmentally protecting said cells; and
a positive bus bar connected to the anode of a first cell of said module and a negative bus bar connected to the cathode of a last cell of said module,
wherein said first area extends beyond said second area by a stripped peripheral zone.

2. A thin film solar module as claimed in claim 1, further comprising:
a cover for protecting said module against atmospheric humidity, while leaving an air cavity about said cells; and
means for fixing said cover to said substrate, while leaving an as large stripped peripheral zone as possible.

3. A thin film solar module as claimed in claim 1 further comprising, within said stripped peripheral zone, an isolated strip of material of the same composition as said cathodes, provided around the perimeter of said second area, wherein said negative bus bar contacts said isolated strip to connect same to the cathode of said first cell.

4. A thin film solar module as claimed in claim 1 or 3, wherein said substrate is soda-lime glass and said cathode is SnO₂.

5. A thin film solar module as claimed in claim 2, wherein said air cavity is connected into an air circuit to actively circulate dry air along the back of the cells, for extracting the thermal energy generated by said cells when the module is exposed to solar radiation.

6. A thin film solar module comprising:
a soda-lime glass substrate having a first area; and
a plurality of photovoltaic cells supported on said glass substrate, said cells arranged in an array occupying a second area on said first area,
wherein said second area is arranged to leave a peripheral zone of said glass around said array.

7. A module as claimed in claim 6, further comprising:
a cover for encapsulating said array while providing an air cavity about said photovoltaic cells; and
means for fixing said cover to said peripheral zone for protecting said array from environmental damage.

8. A module as claimed in claim 7, further comprising means for displacing air through said air cavity to collect the heat dissipated by said array when exposed to solar light.

9. A module as in claim 6, wherein each said cell comprises:
a SnO₂ transparent cathode electrode deposited on said soda-lime glass substrate,
a photosensitive semiconductor layer;
an anode electrode; and
a high resistivity layer for electrically separating the cells from each other, while allowing electrical connectivity between the electrodes of neighboring cells, and
wherein said a first cell of said array is connected with said respective cathode to a first bus bar and a last cell of said array is connected to a second bus bar for enabling electrical connection of said module to an external circuit.

10. A module as claimed in claim 8, further comprising:
an isolated strip of SnO₂ on said peripheral zone and along said peripheral zone dividing said peripheral zone into a first stripped zone at the periphery of said glass substrate and a second stripped zone at the periphery of said array; and
means for connecting said isolated strip with the SnO₂ cathode of said first cell in the module.
